(19) United States
(12) Patent Application Publication
(10) Pub. No.: US 2023/0060799 A1
(43) Pub. Date: Mar. 2, 2023

(54) IMPRINT APPARATUS, METHOD OF IMPRINTING, METHOD OF MANUFACTURING ARTICLE, AND PROGRAM THEREFOR

(71) Applicant: CANON KABUSHIKI KAISHA, Tokyo (JP)

(72) Inventors: Naoya Tsurumi, Tochigi (JP); Yuki Saito, Tochigi (JP)

(21) Appl. No.: 17/874,785

(22) Filed: Jul. 27, 2022

(30) Foreign Application Priority Data
Aug. 31, 2021 (JP) 2021-141294

(51) Int. Cl. B29C 59/00; B29C 59/02

(52) U.S. Cl. CPC B29C 59/002; B29C 59/026; B29C 2037/903

(57) ABSTRACT

An imprint apparatus performing a pattern formation on an imprint material on a substrate by bringing the imprint material on the substrate and a mold into contact with each other, includes: an imprint unit configured to perform the pattern formation; and a control unit configured to control an operation of the imprint unit, in which the control unit performs a control such that the pattern formation is performed on all shot regions, in which no foreign substance exists, on a plurality of substrates using a first mold based on a foreign substance information on the substrate, and then the pattern formation is performed on all shot regions where the foreign substance exists on the plurality of substrates using a second mold different from the first mold.

### BACKGROUND OF THE INVENTION

### Field of the invention

The present invention relates to an imprint apparatus, a method of imprinting, a method of manufacturing an article, and a program therefor.

### Description of the Related Art

An article having a fine structure such as a semiconductor device or a MEMS can be manufactured using a molding apparatus such as a projection exposure apparatus or an imprint apparatus. In such a molding apparatus, the presence of foreign substance on the substrate results in the failure of the manufactured article. In addition, since the imprint material (ultraviolet curing resin) on the substrate and the mold are brought into contact with each other to mold the imprint material in the imprint apparatus, the foreign substance present on the substrate damages the mold or shortens the lifetime of the mold.

Therefore, a substrate inspection apparatus for inspecting a foreign substance on a substrate is used. For example, a substrate inspection apparatus disclosed in Japanese Patent Application Laid-Open No. 2010-69762 irradiates inspection light (laser light) obliquely onto a substrate and detects a foreign substance by receiving scattered light from the foreign substance with a light receiving unit.

However, in the conventional imprint apparatus, since the mold is replaced with a dedicated mold when a shot region in which a foreign substance exists is imprinted, there is a problem in that an overlay error in the same substrate lot increases, and the yield decreases in exchange for preventing the mold from being damaged. Further, when a plurality of foreign substances are present in the same lot, the number of times of mold replacement increases in accordance with the number of shot regions in which foreign substances are present, and thus there is also a problem in that throughput decreases.

### SUMMARY OF THE INVENTION

The present invention provides an imprint apparatus that prevents damage to a mold while preventing a decrease in yield and minimizing a decrease in throughput.

According to an aspect of the present invention, an imprint apparatus performing a pattern formation on an imprint material on a substrate by bringing the imprint material on the substrate and a mold into contact with each other, includes: an imprint unit configured to perform the pattern formation; and a control unit configured to control an operation of the imprint unit, in which the control unit performs a control such that the pattern formation is performed on all shot regions, in which no foreign substance exists, on a plurality of substrates using a first mold based on a foreign substance information on the substrate, and then the pattern formation is performed on all shot regions where the foreign substance exists on the plurality of substrates using a second mold different from the first mold.

Further features of the present invention will become apparent from the following description of exemplary embodiments with reference to the attached drawings.

### BRIEF DESCRIPTION OF THE DRAWINGS

FIG. 1 is a diagram illustrating an imprint apparatus according to a first embodiment.

FIG. 2 is a flowchart of an imprinting method according to Example 1 of the first embodiment.

FIG. 3 is a flowchart of an imprinting method according to Example 2 of the first embodiment.

FIG. 4 shows a substrate processing apparatus according to a second embodiment.

FIG. 5A is a diagram showing a method for producing an article of the present invention.

FIG. 5B is a diagram showing a method for producing an article of the present invention.

FIG. 5C is a diagram showing a method for producing an article of the present invention.

FIG. 5D is a diagram showing a method for producing an article of the present invention.

FIG. 5E is a diagram showing a method for producing an article of the present invention.

FIG. 5F is a diagram showing a method for producing an article of the present invention.

### DESCRIPTION OF THE EMBODIMENTS

Hereinafter, preferred embodiments of the present invention will be described in detail with reference to the accompanying drawings.

It should be noted that the drawings shown below are drawn on a scale different from the actual scale in order to facilitate understanding of the present embodiment.

### Embodiment 1

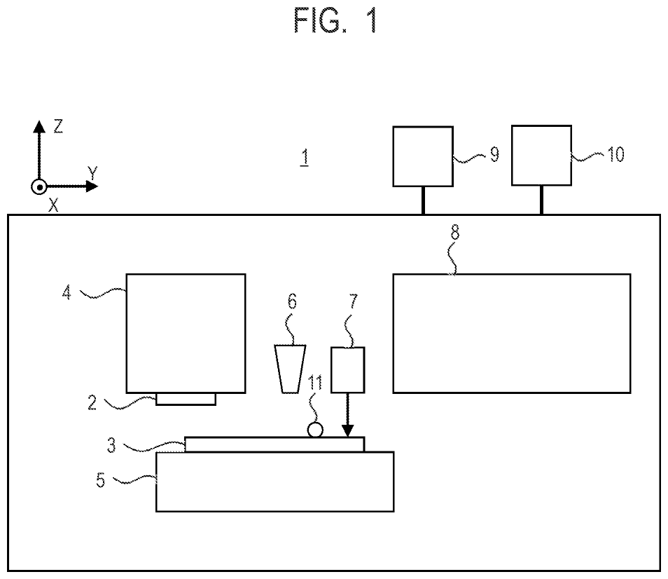

FIG. 1 is a view of an imprint apparatus according to the first embodiment. Hereinafter, the configuration of the imprint apparatus will be described in accordance with an XYZ orthogonal coordinate system in which a plane parallel to the surface of the substrate is an XY plane. Typically, the XY plane is a horizontal plane, and the Z axis is a vertical direction.

The imprint apparatus 1 according to this embodiment includes an imprint head (imprint unit) 4, a substrate stage 5, a nozzle 6, a substrate inspection unit 7, a substrate storage unit 8, a storage unit 9, and a control unit 10.

The substrate stage 5 is a stage that moves in the horizontal direction while holding the substrate 3.

The nozzle 6 discharges the imprint material onto the substrate 3.

The imprint head 4 holds the mold 2, controls the posture of the mold 2, and performs vertical driving for bringing the concave-convex pattern of the mold 2 into contact with the imprint material to imprint the pattern. Thus, the imprint material (resin) on the substrate 3 and the mold 2 on which the pattern is formed are brought into contact with each other to form the pattern on the imprint material on the substrate 3.

A substrate inspection unit 7 detects a foreign substance 11 on the substrate 3, and stores position information of the detected foreign substance 11 in a storage unit 9.

In general, in the substrate inspection unit 7, a very sensitive photodetector such as a photomultiplier tube is used in order to enable detection of a fine foreign substance of about several tens nm. In a photomultiplier tube, electrons generated in a photocathode by incident light are accelerated by a high voltage and then collide with a plurality of stages of dynodes that generate secondary electrons. The current accumulated until passing through the last stage dynode is collected at the anode as an amplified signal. As described above, in general, a substrate inspection apparatus that performs a foreign substance inspection on a substrate irradiates the substrate with laser light at an oblique incidence and detects the presence or absence of a foreign substance by receiving scattered light generated from the foreign substance with a light receiving unit.

Here, with respect to the detection of a foreign substance, a state in which a minute object such as a particle is present on the surface of the substrate 3 is described as a state in which a foreign substance is detected, but the present invention is not limited thereto. For example, since the substrate inspection unit 7 analyzes the intensity distribution of the scattered light from the surface of the substrate 3 to determine the abnormality of the surface of the substrate 3, various states of the surface of the substrate 3 (a foreign substance, a flaw on the substrate surface, a chip, and the like) can be recognized as the abnormality of the surface of the substrate 3, and these are collectively described as the foreign substance information.

The substrate storage unit 8 may store the substrate 3 therein.

The substrate 3 is carried into the imprint apparatus 1 by a substrate conveyance mechanism (not illustrated) and mounted on the substrate stage 5. The substrate conveyance mechanism can also convey the substrate 3 to the substrate storage unit 8, and the substrate 3 on which the imprint process has been completed is conveyed out of the imprint apparatus 1.

The mold 2 is conveyed by a mold conveyance mechanism (not shown) and held by the imprint head 4.

As the imprint material, a curable composition (also referred to as a resin in an uncured state) which is cured by applying energy for curing is used. As the energy for curing, an electromagnetic wave, heat or the like is used. As the electromagnetic waves, for example, light such as infrared rays, visible rays, and ultraviolet rays having wavelengths selected from the range of 10 nm or more and 1 mm or less is used.

The curable composition is a composition that is cured by light irradiation or heating. The photocurable composition that is cured by irradiation with light contains at least a polymerizable compound and a photopolymerization initiator, and may contain a non-polymerizable compound or a solvent as necessary. The non-polymerizable compound is at least one selected from the group consisting of a sensitizer, a hydrogen donor, an internal release agent, a surfactant, an antioxidant, a polymer component, and the like.

The imprint material may be applied in the form of a film onto the substrate by a spin coater or a slit coater. Further, the imprint material may be applied onto the substrate by the liquid ejecting head in the form of droplets, or in the form of islands or films formed by connecting a plurality of droplets. The viscosity (viscosity at 25° C.) of the imprint material is, for example, 1 mPa·s or more and 100 mPa·s or less.

### Exemplary Embodiment 1

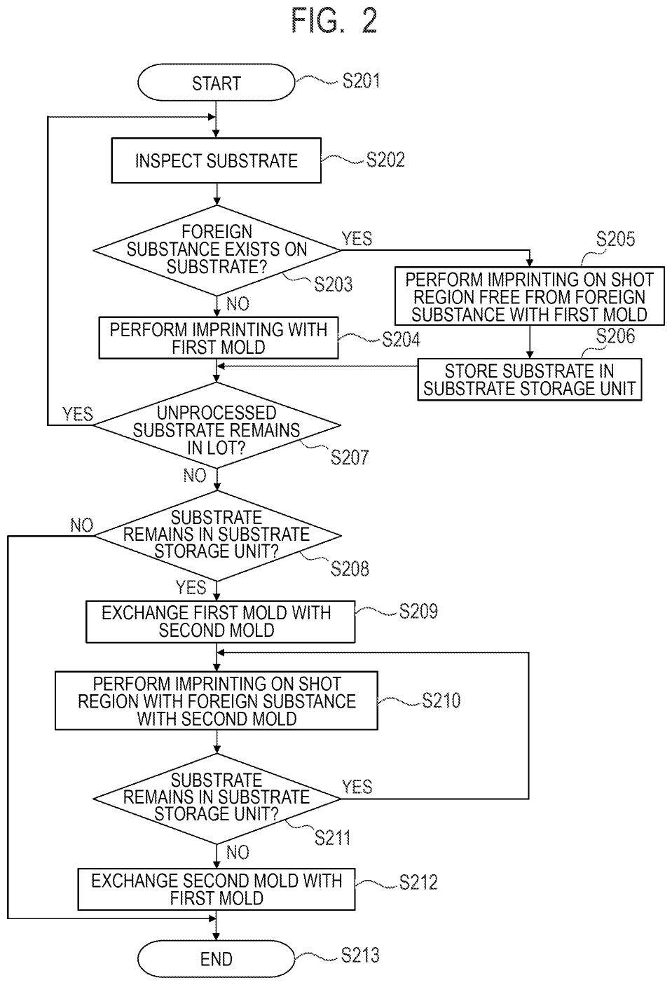

The operation of the imprint apparatus 1 according to first exemplary embodiment 1 will be described below with reference to FIGS. 1 and 2. FIG. 2 is a flowchart illustrating an imprint method for a substrate lot (a plurality of substrates) according to first exemplary embodiment. The substrate processing operation of the imprint apparatus 1 is controlled by a control unit 10.

The imprint apparatus 1 starts sequence control of substrate processing from a process S201.

When the substrate processing is started, in step S202, the substrate 3 is mounted on the substrate stage 5 by the substrate conveyance mechanism. Before or after the substrate 3 is mounted on the substrate stage 5, the substrate 3 may be positioned at a desired rotation angle or a desired center position with respect to the substrate stage 5 by a position detection apparatus or a positioning apparatus (not shown). This positioning can be performed by measuring a positioning mark provided on the outer shape or outer peripheral portion of the substrate 3.

Thereafter, when the substrate 3 mounted on the substrate stage 5 passes through the inspection region of the substrate inspection unit 7, the presence or absence of the foreign substance 11 present on the surface of the substrate 3 is inspected by the substrate inspection unit 7. As information on the detected foreign substance 11, information on at least the position among information on the position, size, shape, and material of the foreign substance 11 on the substrate 3 is stored in the storage unit 9 (memory) or the control unit 10 (or an internal computer) in the imprint apparatus 1. The storage unit 9 functions as a storage means. After storing the information on the detected foreign substance 11, the control unit 10 or the like is notified of the acquired information. The foreign substance information may be displayed on an operation screen of the computer apparatus so that the user can confirm the foreign substance information through the screen.

Next, in step S203, when the foreign substance 11 is not detected on the surfaces of the substrates 3 based on the substrate inspection result in step S202, the process proceeds to step S204. On the other hand, when the foreign substance 11 is detected, the process proceeds to step S205.

In step S204, all shot regions on the substrate 3 are imprinted with the first mold 2. That is, the imprint material is supplied to the shot region on the substrate 3 by the nozzle 6, and the concave-convex pattern of the first mold 2 is brought into contact with the imprint material on the substrate 3. In this state, the imprint material is irradiated with ultraviolet rays or the like to be photo-cured, thereby forming a pattern. The substrate 3 for which imprinting of all the shot regions has been completed is unloaded from the imprint apparatus 1 by the substrate conveyance mechanism.

In step S205, the shot region in which the foreign substance 11 is detected is not imprinted by the first mold 2, and only the other shot regions in which the foreign substance 11 is not detected are imprinted by the first mold 2. Subsequently, in step S206, the substrate 3 on which imprinting has been completed except for the shot region in which the foreign substance 11 has been detected is transported to the substrate storage unit 8 by the substrate conveyance mechanism. The substrate storage unit 8 is configured to hold the substrate 3 therein, and can store the substrate 3.

Next, in step S207, it is determined that all the substrates 3 in the same lot have been processed, and if there is no unprocessed substrate 3 left, the process proceeds to step S208. When an unprocessed substrate 3 remains, the process returns to step S202, and the processes of S202 to S207 are repeated for the next substrate 3.

In step S208, it is determined whether or not the substrate 3 is stored in the substrate storage unit 8. When no substrate 3 is stored, the process proceeds to step S213, and the process for the substrate lot is ended. On the other hand, when the substrate 3 is stored in the substrate storage unit 8, the process proceeds to step S209. Here, in order to store all the substrates 3 in which the foreign substances 11 are detected in the substrate storage unit 8, the substrate storage unit 8 is configured to store the same number of substrates 3 as the number of substrate lots, and it is preferable that all the substrates 3 of the same lot can be stored at the maximum.

In step S209, the first mold 2 is recovered from the imprint head 4 by a mold conveyance mechanism (not shown), and instead, the second mold 2 is conveyed and held by the imprint head 4. The second mold 2 is used exclusively for imprinting a shot region in which a foreign substance 11 is present, and is used to avoid the risk of damage to the first mold 2 and the substrate 3 due to contact with the foreign substance 11. Therefore, the second mold 2 does not needs to have a concave-convex pattern, and only needs to be capable of imprinting.

Subsequently, in step S210, the substrate 3 stored in the substrate storage unit 8 is mounted on the substrate stage 5, and the entire shot regions in which the non-imprinted foreign substance 11 is present are imprinted with the second mold 2. Thus, the imprinting of all the shot regions on the substrate 3 is completed, and the substrate 3 is unloaded from the imprint apparatus 1 by the substrate conveyance mechanism.

Next, in step S211, it is determined that the substrate 3 is stored in the substrate storage unit 8. When the substrate 3 is stored, the process returns to step S210, and the processes of S210 to S211 are repeated for the next stored substrate 3. When the substrate 3 is not stored in the substrate storage unit 8, the process proceeds to step S212. In step S212, the second mold 2 is collected by the mold conveyance mechanism, and the first mold 2 is held by the imprint head 4. Thereafter, the process proceeds to step S213, and the processing for the substrate lot is ended.

Constituent members related to substrate processing such as the imprint head 4, the substrate stage 5, the nozzle 6, and the substrate inspection unit 7 of the imprint apparatus 1 according to the present embodiment are connected to a control unit 10 illustrated in FIG. 1 via a wired or wireless communication line. The control unit 10 controls these operations. The control unit 10 includes a CPU that reads a computer program for controlling various operations from the storage unit 9 and executes the computer program. The control unit 10 may be provided inside the imprint apparatus 1, or may be installed in a place different from the imprint apparatus 1 to remotely control the imprint apparatus 1.

The configuration of the imprint apparatus 1 and the processing sequence for the substrate lot described above can prevent the mold 2 from being damaged due to contact with the foreign substance 11 during imprinting.

Further, in the present embodiment, there is an effect of preventing a decrease in yield in the same substrate lot while preventing damage to the mold 2. This is because a shot region in the same lot where there is no foreign substance 11 can be imprinted with the mold 2 maintained in the same holding state.

When the holding of the mold 2 is released, the transfer accuracy of the concave-convex pattern changes due to a change in the position or posture of the mold 2, and the overlay error increases. In the present embodiment, since the mold 2 is replaced after the imprinting of all the shot regions in the same lot in which the foreign substance 11 does not exist is completed, the overlay error is not affected by the replacement of the mold 2 except for the shot region in which the foreign substance 11 exists. Although it is necessary to imprint a shot region in which the foreign substance 11 is present in terms of processing in a subsequent step, overlay accuracy comparable to that in a shot region in which the foreign substance 11 is not present is not required.

Furthermore, in this embodiment, even if there are a plurality of substrates 3 including shot regions in which the foreign substance 11 is present in the same lot, the number of times of exchanging the mold 2 is only two at the maximum. Therefore, it is possible to obtain an effect of minimizing a decrease in throughput due to replacement of the mold 2 while preventing damage to the mold 2.

### Exemplary Embodiment 2

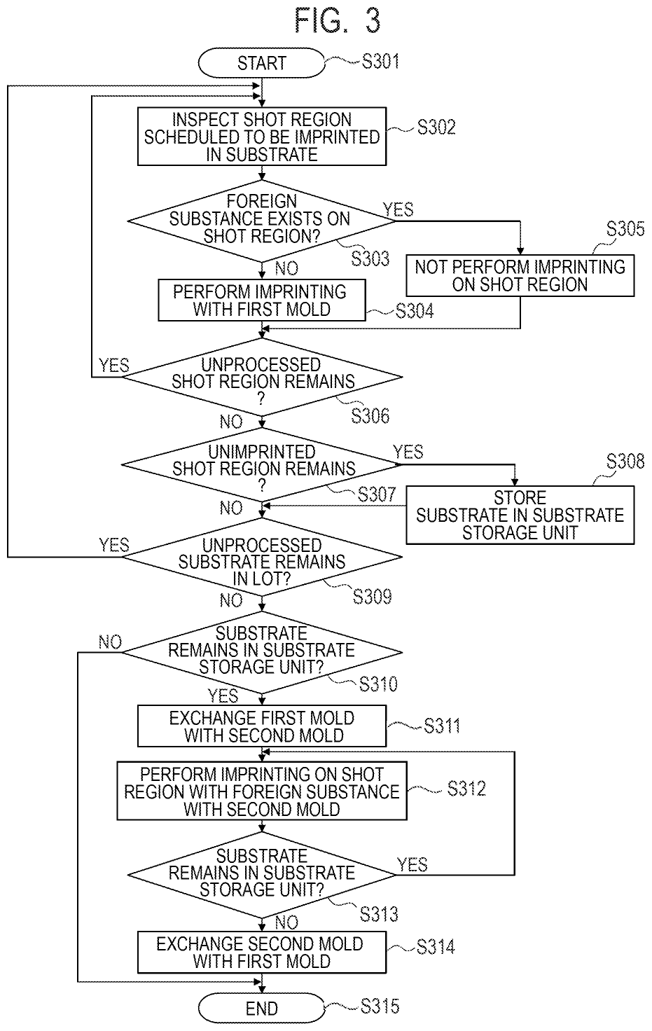

The operation of the imprint apparatus 1 according to the second exemplary embodiment will be described below with reference to FIGS. 1 and 3. FIG. 3 is a flowchart showing an imprinting method for a substrate lot according to the second exemplary embodiment.

In this exemplary embodiment, the inspection of the substrate 3 by the substrate inspection unit 7 is performed for each shot region. That is, only a shot region to be processed on the substrate 3 is inspected, and immediately thereafter, the shot region is imprinted. This process is repeated for all shot regions in the substrate 3.

The imprint apparatus 1 starts sequence control of substrate processing from step S301. When the substrate processing is started, the substrate 3 is mounted on the substrate stage 5 by the substrate conveyance mechanism in step S302. When the substrate 3 passes through the inspection region of the substrate inspection unit 7, the presence or absence of the foreign substance 11 present on the surface of the shot region to be imprinted is inspected by the substrate inspection unit 7.

Next, in step S303, when the foreign substance 11 is not detected on the surfaces of the shot regions on the basis of the inspection result of the shot regions in step S302, the process proceeds to step S304. On the other hand, when the foreign substance 11 is detected, the process proceeds to step S305. In step S304, a shot region in which the foreign substance 11 is not detected is imprinted with the first mold 2. On the other hand, in step S305, imprint is not performed on a shot region in which the foreign substance 11 is detected.

Subsequently, in step S306, it is determined whether or not a series of processing of substrate inspection and imprinting has been performed for all shot regions in the substrate 3. If there is no unprocessed shot region, the process proceeds to step S307. When there is an unprocessed shot region, the process returns to step S302, and the processes of S302 to S306 are repeated for the next shot region.

In step S307, it is determined whether or not imprinting has been performed on all shot regions in the substrate 3. If there is no non-imprinted shot region, the process proceeds to step S309. On the other hand, if there is a non-imprinted shot region, the process proceeds to step S308. In step S308, the substrate 3 having a non-imprinted shot region is transported to and stored in the substrate storage unit 8.

Subsequent steps S309 to S315 have the same flow as the steps S207 to S213 in FIG. 2.

### Second Embodiment

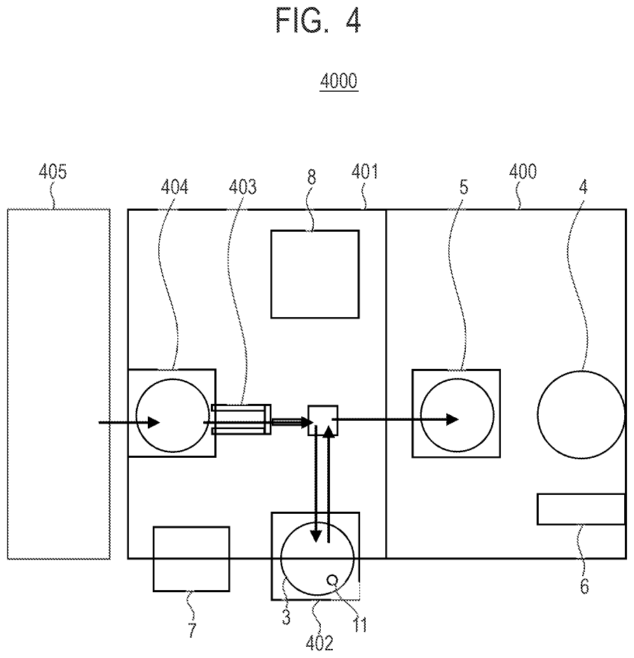

Next, a second embodiment will be described with reference to FIG. 4. FIG. 4 shows a configuration of a substrate processing apparatus 4000 according to a second embodiment. The substrate processing apparatus 4000 includes an imprint apparatus 400 and a substrate inspection apparatus 401. In the second embodiment, the substrate inspection apparatus 401 is configured as an external apparatus of the imprint apparatus 400, and the foreign substance inspection information is transmitted from the substrate inspection apparatus 401 to the imprint apparatus 400 by communication between apparatuses.

The imprint apparatus 400 includes an imprint head 4, a substrate stage 5, and a nozzle 6. A substrate inspection apparatus 401 can be connected to the imprint apparatus 400.

The substrate inspection apparatus 401 includes a substrate stage 402, a substrate conveyance mechanism 403, a station 404, a substrate inspection unit 7, and a substrate storage unit 8. An auxiliary apparatus 405 such as a coater/developer may be connected to the substrate inspection apparatus 401.

The auxiliary apparatus 405 is an apparatus for disposing the composition on the substrate 3, and supplies the substrate 3 on which the composition is disposed to the station 404 in the substrate inspection apparatus 401. Subsequently, in the substrate inspection apparatus 401, the substrate 3 supplied to the station 404 is transferred to the substrate stage 402 by the substrate conveyance mechanism 403. When the substrate 3 mounted on the substrate stage 402 passes through the inspection region of the substrate inspection unit 7, the presence or absence of the foreign substance 11 present on the surface is inspected by the substrate inspection unit 7.

The inspected substrate 3 is mounted on the substrate stage 5 of the imprint apparatus 400 by the substrate conveyance mechanism 403. The substrate storage unit 8 stores the substrate 3 on which imprinting has been completed except for the shot region in which the foreign substance 11 is present. Here, the substrate storage unit 8 may be configured in the imprint apparatus 400, or may be configured in both the substrate inspection apparatus 401 and the imprint apparatus 400.

Although FIG. 4 illustrates the substrate processing apparatus 4000 in which one imprint apparatus 400 is connected to one substrate inspection apparatus 401, the substrate processing apparatus 4000 may be a so-called cluster type substrate processing apparatus in which a plurality of imprint apparatuses 400 are connected. In this case, the result of the substrate inspection performed by the substrate inspection apparatus 401 is transmitted to the imprint apparatus 400 to which the substrate 3 is conveyed. Each imprint apparatus 400 can perform substrate processing using information such as the position and size of the foreign substance 11 adhering to the substrate 3 by acquiring the inspection result obtained by the substrate inspection apparatus 401.

When substrates 3 of different lots are processed by the connected imprint apparatuses 400, the number of substrates 3 that can be stored in the substrate storage unit 8 is determined in accordance with the number of substrates in lot to be simultaneously processed in the substrate processing apparatus 4000. Specifically, it is preferable that the same number of substrates 3 as those in all substrates in lot to be simultaneously processed can be stored. Alternatively, each imprint apparatus 400 may be provided with a substrate storage unit 8 capable of storing all substrates 3 of the same lot.

The flow chart showing the imprinting method for the substrate lot of this embodiment is the same as that of the first embodiment, and is shown in FIGS. 2 and 3.

The second embodiment is different from the first embodiment in that a substrate inspection unit 7 and a substrate storage unit 8 are provided in a substrate inspection apparatus 401. Therefore, in the flowchart of FIG. 2, the movement of the substrate 3 between the substrate inspection apparatus 401 and the imprint apparatus 400 is realized by the substrate conveyance mechanism 403. In addition, since the substrate stage 402 is used for the substrate inspection and the substrate stage 5 is used for the imprint process, both processes can be performed in parallel. With this configuration, the time required for the substrate inspection is shortened, and the throughput of the substrate processing apparatus 4000 is improved.

In this embodiment, as in the first embodiment, it is possible to prevent damage to the mold 2, to prevent a decrease in yield in the same substrate lot, and to minimize a decrease in throughput of the substrate processing apparatus 4000.

### <Embodiment of Method for Producing Article>

A method for manufacturing a device (a semiconductor integrated circuit element, a liquid crystal display element, or the like) as an article includes a step of forming a pattern on a substrate (a wafer, a glass plate, or a film-like substrate) using the above-described imprint apparatus.

The manufacturing method may further include a step of etching the substrate on which the pattern is formed.

When another article such as a patterned medium (recording medium) or an optical element is manufactured, the manufacturing method may include another process of processing a substrate on which a pattern is formed instead of etching.

The method for manufacturing an article according to the present embodiment is advantageous in at least one of performance, quality, productivity, and production cost of the article as compared with a conventional method.

### (Example of Article Manufacturing Method)

The pattern of the cured product formed using the imprint apparatus is used permanently in at least a part of various articles or temporarily when various articles are manufactured. The article is an electric circuit element, an optical element, a MEMS, a recording element, a sensor, a mold, or the like. Examples of the electric circuit elements include volatile or nonvolatile semi-conductor memories such as DRAM, SRAM, flash memory, and MRAM, and semi-conductor elements such as LSI, CCD, image sensor, and FPGA. Examples of the optical element include a micro lens, a light guide, a waveguide, an antireflection film, a diffraction grating, a polarizing element, a color filter, a light-emitting element, a display, and a solar cell. Examples of the MEMS include a DMD, a micro-channel, and an electromechanical transducer. Examples of the recording elements include optical disks such as CD, DVD, magnetic disks, magneto-optical disks, and magnetic heads. Examples of the sensor include a magnetic sensor, an optical sensor, a gyro sensor, and the like. Examples of the mold include a mold for imprinting.

The pattern of the cured product is used as it is as a constituent member of at least a part of the article, or is used temporarily as a resist mask. After the etching or the ion implantation is performed, the resist mask is removed.

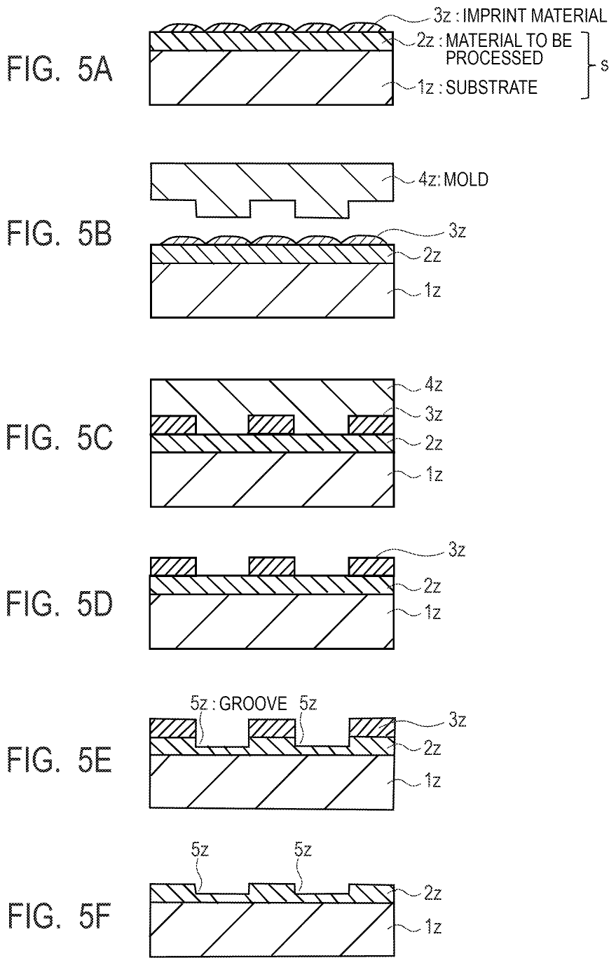

Next, a method for producing the article of the present invention will be described. As shown in FIG. 5A, a substrate 1z made of silica glass or the like is prepared, and then an imprint material 3z is applied to the surfaces of the substrate 1z having the material to be processed 2z by an inkjet method or the like. If necessary, a layer of another material such as metals or metallic compounds may be provided on the surface the substrate 1z.

As shown in FIG. 5B, the side on which the concave-convex pattern is formed of the mold 4z for imprinting is made to face the imprint material 3z on the substrate 1z. As shown in FIG. 5C, the substrate 1z to which the imprint material 3z has been applied and the mold 4z are brought into contact with each other and pressurized. The imprint material 3z is filled in a space between the mold 4z and the substrate 1z. When light is irradiated through the mold 4z in this state, the imprint material 3z is cured.

As illustrated in FIG. 5D, when the mold 4z and the substrate 1z are separated from each other after the imprint material 3z is cured, a pattern of a cured product of the imprint material 3z is formed on the substrate 1z. Thus, an article having the pattern of the cured product as a constituent member can be obtained. When the substrate 1z is etched as shown in FIGS. 5E and 5F using the pattern of the cured product as a mask in the state of FIG. 5D, an article in which the concave portions and the convex portions are inverted with respect to the mold 4z, for example, a mold for imprinting can be obtained.

### Other Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2021-141294, filed Aug. 31, 2021, which is hereby incorporated by reference herein in its entirety.

What is claimed is:

1. An imprint apparatus performing a pattern formation on an imprint material on a substrate by bringing the imprint material on the substrate and a mold into contact with each other, comprising: an imprint unit configured to perform the pattern formation; and a control unit configured to control an operation of the imprint unit,
wherein the control unit performs a control such that the pattern formation is performed on all shot regions, in which no foreign substance exists, on a plurality of substrates using a first mold based on a foreign substance information on the substrate, and then the pattern formation is performed on all shot regions where the foreign substance exists on the plurality of substrates using a second mold different from the first mold.

2. The imprint apparatus according to claim 1, comprising an inspection unit configured to inspect a foreign substance on the substrate,
wherein the foreign substance information is acquired by the inspection unit.

3. The imprint apparatus according to claim 1, wherein the foreign substance information on the substrate is a foreign substance information from an external apparatus.

4. The imprint apparatus according to claim 1, comprising a substrate storage unit configured to store the substrate including the shot region in which the foreign substance exists,
wherein the control unit performs the pattern formation on all shot regions, in which the foreign substance does not exist, of the plurality of substrates with the first mold, stores the substrate including the shot region in which the foreign substance exists in the substrate storage unit, and performs the pattern formation on all shot regions, in which the foreign substance exists, of the plurality of substrates with the second mold different from the first mold.

5. The imprint apparatus according to claim 4, wherein the substrate storage unit can store a same number of substrates as a number of the plurality of substrates.

6. The imprint apparatus according to claim 1, wherein the foreign substance information includes an information on a position of the foreign substance on the substrate.

7. The imprint apparatus according to claim 6, wherein the foreign substance information includes at least one of information on a size, a shape, and a material of the foreign substance.

8. The imprint apparatus according to claim 1, wherein the plurality of substrates are a plurality of substrates in a same substrate lot.

9. The imprint apparatus according to claim 1, comprising a storage unit configured to store the foreign substance information.

10. A method of imprinting by bringing an imprint material on a substrate an imprint material on a substrate and a mold into contact with each other to perform a pattern formation on the imprint material on the substrate, comprising:
performing the pattern formation on all shot regions, in which a foreign substance does not exist, of a plurality of substrates with a first mold based on a foreign substance information on the substrate; and then
performing the pattern formation on all shot regions, in which a foreign substance exists, of the plurality of substrates with a second mold different from the first mold.

11. The method according to claim 10, wherein the foreign substance information includes an information on a position of the foreign substance on the substrate.

12. The method according to claim 10, wherein the foreign substance information includes at least one of information on a size, a shape, and a material of the foreign substance.

13. The method of manufacturing an article, comprising: performing a pattern formation using the imprint apparatus according to claim 1; and processing the substrate on which the pattern has been formed in the step of performing the pattern formation.

14. A program for causing a computer to execute a method of imprinting to perform a pattern formation on an imprint material on a substrate by bringing the imprint material on the substrate and a mold into contact with each other,
wherein the method of imprinting comprises: performing the pattern formation on all shot regions, in which a foreign substance does not exist, of a plurality of substrates with a first mold based on a foreign substance information on the substrate; and then performing the pattern formation on all shot regions, in which a foreign substance exists, of the plurality of substrates with a second mold different from the first mold.
